(19) United States
(12) Patent Application Publication
(10) Pub. No.: US 2009/0032095 A1
(43) Pub. Date: Feb. 5, 2009

(54) Semiconductor Component And Method For Producing It and Use for It

(75) Inventors: Oliver Schultz, Sunnyvale, CA (US); Marc Hofmann, March (DE)

Correspondence Address: GIBSON & DERNIER L.L.P., 900 ROUTE 9 NORTH, SUITE 504, WOODBRIDGE, NJ, 07095, US

(73) Assignee: FRAUNHOFER-GESELLSCHAFT ZUR FORDERUNG DER ANGEWANDTEN FORSCHUNG E.V., MUENCHEN (DE)

(21) Appl. No.: 12/162,755

(22) PCT Filed: Feb. 15, 2007
(86) PCT No.: PCT/EP2007/001325

§ 371 Date: Oct. 6, 2008

(30) Foreign Application Priority Data
Feb. 20, 2006 (DE) 102006007797.0

(51) Int. Cl. H01L 31/0216; H01L 21/31; H01L 23/58; H01L 31/18

(52) U.S. Cl. 136/256; 438/778; 257/632; 438/57; 257/E21.24; 257/E23.002; 257/E31.119

(57) ABSTRACT

The invention relates to a method for the production of a semiconductor component having at least one optically reflective surface in which a silicon wafer, which has an etchable dielectric layer at least in regions on at least one of its surfaces, is provided with a silicon-containing masking layer in order to screen against fluid media. In addition a layer comprising aluminium is deposited on the masking layer and subsequently a thermal treatment of the semiconductor component is undertaken, the result being dissolving of the silicon in the aluminium. Furthermore, the invention relates to a corresponding semiconductor component made of a silicon wafer having at least one optically reflective surface. Semiconductor components of this type are used in particular as solar cells.

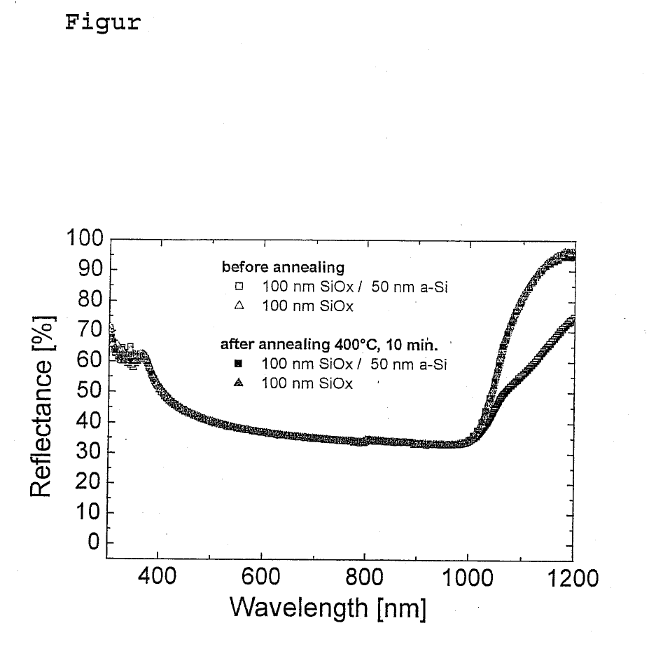

The invention relates to a semiconductor component made of a silicon wafer having at least one optically reflective surface, in which reflective coatings with a high reflection value can be produced simply by applying the method according to the invention.

It is crucial for the economic efficiency of solar cells to increase the efficiency, on the one hand, and, on the other hand, to reduce the thickness of the wafer. The development of the rear side of the solar cell is crucial for this purpose since particularly high requirements in terms of optical and electrical properties are made here. With regard to the optics, as high an internal reflectivity as possible is sought so that light which has penetrated into the wafer from the front side and has not yet been absorbed can be reflected on the cell rear side and thus a possibility again for absorption of the light in the silicon exists. The electrical properties however can be achieved particularly well by using a dielectric passivation layer. Dielectric passivation layers of this type which generally comprise silicon oxide have a refractive index which differs greatly from that of the silicon, which confers advantages in the internal reflection of the light in the solar cell.

The internal reflectivity is then increased further by an additionally deposited metal layer, generally aluminium.

Systems of this type however entail a few problems in production since processing of the silicon disc which has silicon oxide on at least one side is not possible or not readily possible with hydrofluoric acid without etching the silicon oxide.

Approaches for finding a solution to this which provide application of a varnish layer by means of which the silicon oxide is protected at least in regions from the hydrofluoric acid have been known for some time from the state of the art. Approaches of this type to the solution however involve the disadvantage that such a varnish layer must be removed, which is associated with additional process complexity (J. Knobloch et al. “High-efficiency Solar Cells from FZ, CZ and MC Silicon Material”, Proceedings of the 23^{rd} IEEE Photovoltaic Specialists Conference, pp. 271-276, Louisville, Ky., USA, 1993 and O. Schultz et al., “Silicon Oxide/Silicon Nitride Stack System for 20% Efficient Silicon Solar Cells”, 31^{st} IEEE Photovoltaic Specialists Conference, Florida, USA, 2005).

Starting herefrom it was the object of the present invention to provide a method with which the production of semiconductor components of this type is made possible in a simplified process chain. At the same time, also a high internal reflectivity of the thus produced solar cells was however intended to be ensured.

This object is achieved by the method having the features of claim 1 and the semiconductor component having the features of claim 14. A use according to the invention is indicated in claim 19. The further dependent claims reveal advantageous developments.

According to the invention, a method for the production of a semiconductor component having at least one optically reflective surface is provided. This method is based on the fact that a silicon wafer, which has an etchable dielectric layer at least in regions on at least one of its surfaces, is provided with a masking layer made of amorphous silicon or a silicon-containing layer having a silicon content of at least 60% by weight in order to screen against fluid media, the masking layer being deposited on the dielectric layer. An aluminium layer is subsequently deposited on the masking layer. In a further step, thermal treatment of the layer system is then effected, the result being dissolving of the silicon in the aluminium.

An efficient masking of selected regions against the etching of fluid etching media, such as e.g. by hydrofluoric acid, is made possible with the method according to the invention. This can be attributed to the fact that amorphous silicon or silicon-rich layers have high resistance to hydrofluoric acid.

A preferred variant provides that the masking layer comprises amorphous silicon which has particularly high resistance to hydrofluoric acid. A further preferred variant provides that the masking layer comprises silicon nitride. The silicon content thereby is preferably at least 60% by weight, particularly preferred at least 70% by weight.

With respect to deposition of the masking layer, all the methods known from the state of the art can be used, a plasma-enhanced chemical gas phase deposition being preferred. For the deposition of amorphous silicon, preferably silane (SiH₄) and possibly hydrogen (H₂) can be used preferably here as starting substances. The gas phase deposition is effected preferably at a pressure of 20 to 280 Pa, in particular 30 to 75 Pa. The temperature is preferably in the range of 20 to 400° C., in particular 200 to 300° C.

The deposition of the masking layer can be effected also by means of sputtering methods in a further preferred variant.

For the passivation layer, preferably a material is used selected from the group consisting of silicon oxide, silicon nitride, silicon carbide and aluminium oxide.

After deposition of the individual layers, thermal treatment is effected at temperatures in the range of preferably 150 to 950° C. and particularly preferred from 300 to 550° C. The temperature choice is thereby determined via the time window so that a short thermal treatment at a higher temperature leads to the same result as a longer treatment at a lower temperature. As a result of this described temperature treatment, the result is a dissolving process of the silicon in the aluminium. The thereby forming layer made of aluminium and silicon has very high reflection values.

In a further preferred variant of the method according to the invention, after deposition of the masking layer, the latter can be structured by means of laser ablation so that the masking layer can be used as local etching mask.

According to the invention, a semiconductor component made of a silicon wafer is also provided with at least one optically reflective surface. The silicon wafer thereby has a dielectric passivation layer on the at least one optical reflective surface. Furthermore, an aluminium- and silicon-containing reflective layer is applied on the passivation layer, said reflective layer being produced by a thermal treatment.

Surprisingly, it was able to be shown that the semiconductor components according to the invention, relative to systems known from the state of the art comprising a wafer with a silicon oxide layer deposited thereon, have comparably high reflection values. Thus the semiconductor components according to the invention preferably have a reflection value in the range of >90°. This leads at the same time to an efficiency of the solar cell according to the invention of at least 18%.

It is thereby preferred that the semiconductor component according to the invention was produced according to the previously described method.

The method according to the invention is used in particular in the production of solar cells.

The subject according to the invention is intended to be explained in more detail with reference to the subsequent example and the Figure, without wishing to restrict said subject to the special embodiment shown here.

The Figure shows a reflection measurement on a semiconductor component according to the invention, with a silicon disc (250 μm thickness), a passivation layer made of silicon oxide (100 nm thickness), a masking layer made of amorphous silicon (50 nm thickness) and an aluminium layer (2 μm thickness). Reflection measurements on a system known from the state of the art which has no masking layer is compared thereto.

### EXAMPLE

A layer with a significantly lower refractive index than that of silicon was situated on the rear side of a solar cell. This hereby preferably involves silicon oxide, e.g. produced by thermal oxidation or deposited by known coating methods. Thermal oxides which were produced in a tube furnace at temperatures between 800 and 1050° C. by heating the wafer in an oxygen-containing atmosphere were examined. Deposited oxides were produced from laughing gas (N₂O) and silane (SiH₄) in plasma-enhanced chemical gas phase deposition in a parallel plate reactor. The temperatures varied in the range of 250 and 350° C., the pressure being approx. 1,000 mTorr. The refractive index of the dielectric layer was n>1.45 (measured at 630 nm and RT). The greater the differences in the refractive index between silicon (n 3.6), measured at 630 nm and RT, and the dielectric layer, the better for the internal reflective coating. On this layer, say silicon oxide, aluminium was vapour deposited and a good mirror was produced. The amorphous silicon was then dissolved in the aluminium layer by thermal treatment. The amorphous silicon was thereby produced from silane (SiH₄) and hydrogen (H₂) by plasma-enhanced chemical gas phase deposition (PECVD) in a pressure range of 30 to 75 Pa at temperatures of 200 to 300° C.

The radiation power emerging again on the front side of the semiconductor component according to the invention was measured and set as a ratio with the irradiated power, the reflection value is produced herefrom. In the case of a layer system with amorphous silicon, the reflection value before thermal treatment at 1,200 nm is approx. 75%. By means of heating the solar cell for 10 min. at 400° C., the silicon dissolves in the aluminium and the reflection rises to above 90%, just as is the case also without the amorphous silicon in this layer system (see Figure).

1. A method for the production of a semiconductor component having at least one optically reflective surface in which a silicon wafer, which has an etchable dielectric layer at least in regions on at least one of its surfaces, is provided, a silicon-containing masking layer with a silicon content of at least 60% by weight is subsequently deposited on the layer in order to screen against fluid media and a layer made of aluminium is deposited on the masking layer and also dissolving of the silicon in the aluminium is effected by a thermal treatment.

2. The method according to claim 1, wherein the masking layer is resistant to hydrofluoric acid.

3. The method according to claim 1, wherein the masking layer comprises amorphous silicon.

4. The method according to claim 1, wherein the masking layer comprises silicon nitride.

5. The method according to claim 4, wherein the silicon nitride has a silicon content of one of: at least 60% by weight, and at least 70% by weight.

6. The method according to claim 1, wherein the masking layer is deposited by means of plasma-enhanced chemical gas phase deposition.

7. The method according to claim 6, wherein at least one of silane and hydrogen are used as starting substance.

8. The method according to claim 6, wherein the gas phase deposition is effected at a pressure of one of: 20 to 280 Pa, and 30 to 75 Pa.

9. The method according to claim 6, wherein the gas phase deposition is effected at a temperature of one of: 20 to 400° C., and 200 to 300° C.

10. The method according to claim 1, wherein the masking layer is deposited by means of sputtering methods.

11. The method according to claim 1, wherein the dielectric layer is selected from the group consisting of silicon oxide, silicon nitride, silicon carbide and aluminium oxide.

12. The method according to claim 1, wherein the thermal treatment is implemented at temperatures in the range of one of: 150 to 950° C., and 300 to 550° C.

13. The method according to claim 1, wherein after depositing the masking layer, the latter is structured by means of laser ablation.

14. A semiconductor component made of a silicon wafer having at least one optically reflective surface, wherein the silicon wafer has a dielectric layer on the at least one optically reflective surface and a reflective layer which is produced by thermal treatment and contains silicon.

15. The semiconductor component according to claim 14, wherein the dielectric layer is selected from the group consisting of: silicon oxide, silicon nitride, silicon carbide and aluminium oxide.

16. The semiconductor component according to claim 14, wherein the reflective surface of the semiconductor component has a reflection value in the range of greater than 90%.

17. The semiconductor component according to claim 14 wherein the semiconductor component is a solar cell.

18. The semiconductor component according to the solar cell has an efficiency of one of: at least 18%, and 20%, measured according to standard conditions according to IEC 60904-1 to 60904-10.

19. The semiconductor component according to claim 14, produced according to the method claim 1.

20. A method for the production of solar cells, wherein the solar cells are produced according to the method of claim 1.
